(19) United States
(12) Patent Application Publication
(10) Pub. No.: US 2013/0001734 A1
(43) Pub. Date: Jan. 3, 2013

(54) SCHOTTKY DIODE STRUCTURE

(75) Inventors: Ming-Tzong Yang, Baoshan Township (TW); Tung-Hsing Lee, Lujhou City (TW)

(73) Assignee: MEDIATEK INC., Hsin-Chu (TW)

(21) Appl. No.: 13/175,230

(22) Filed: Jul. 1, 2011

(51) Int. Cl. H01L 29/872

(52) U.S. Cl. 257/476; 257/E29.338

(57) ABSTRACT

A Schottky diode structure includes a semiconductor substrate having an anode region and a cathode region. A lightly doped region with a predetermined conductivity type is in the semiconductor substrate. A metal contact overlies the lightly doped region and corresponds to the cathode region to serve as a cathode. A metal silicide layer is beneath and electrically connected to the metal contact, wherein the metal silicide layer, directly under the metal contact, is in direct contact with the lightly doped region. A heavily doped region with the predetermined conductivity type is in the lightly doped region and corresponds to the anode region to serve as an anode.

### BACKGROUND OF THE INVENTION

1. Field of the Invention

The invention relates to a semiconductor-based diode and more particularly to a Schottky diode structure with silicide.

2. Description of the Related Art

A Schottky diode (or a “Schottky barrier diode”) is a well known semiconductor device and is commonly used in electronic applications, such as power circuits or voltage converters. Such a Schottky diode is typically formed by a metal-semiconductor junction. For example, a barrier metal, such as aluminum, is deposited on a surface of a lightly doped n-type or p-type semiconductor to form the Schottky diode. The barrier metal contacting the semiconductor forms an anode of the Schottky diode. Moreover, a heavily doped n-type or p-type region electrically contacting with the lightly doped n-type or p-type semiconductor forms a cathode of the Schottky diode.

A Schottky diode is characterized by a low forward voltage (i.e., turn on voltage) as compared to a traditional p-n junction diode. In the conventional fabrication of the Schottky diode, however, overetching during contact formation may damage the metal/semiconductor interface, thereby changing the physical and/or electrical characteristics thereof As a result, the variability of the typical manufacturing process may limit the reliability and stability of the Schottky diode. However, manufacturing costs and device size are increased due to formation of the guard ring and this does not meet the demands of current or future electronic applications.

Accordingly, there is a need to develop novel Schottky diode structure designs which are capable of mitigating the aforementioned problems.

### BRIEF SUMMARY OF THE INVENTION

An exemplary embodiment of a Schottky diode structure comprises a semiconductor substrate having an anode region and a cathode region. A lightly doped region with a predetermined conductivity type is in the semiconductor substrate. A metal contact overlies the lightly doped region and corresponds to the cathode region to serve as a cathode. A metal silicide layer is beneath and electrically connected to the metal contact, wherein the metal silicide layer, directly under the metal contact, is in direct contact with the lightly doped region. A heavily doped region with the predetermined conductivity type is in the lightly doped region and corresponds to the anode region to serve as an anode.

Another exemplary embodiment of a semiconductor device structure comprises a semiconductor substrate having a well region with a predetermined conductivity type therein. An isolation structure is disposed in the well region to define a first active area and a second active area therein and separated from each other by the isolation structure. A metal contact overlies the lightly doped well region of the first active area. A first metal silicide layer is beneath and electrically connected to the metal contact, wherein the first metal silicide layer, directly under the metal contact, is in direct contact with the well region. A heavily doped region with the predetermined conductivity type is in the well region of the second active area.

### BRIEF DESCRIPTION OF DRAWINGS

The invention can be more fully understood by reading the subsequent detailed description and examples with references made to the accompanying drawings, wherein:

FIG. 1A shows a plan view of an exemplary embodiment of a semiconductor device according to the invention;

FIG. 1B shows a cross section along line 1B-1B′ of FIG. 1A;

FIG. 2A shows a plan view of an exemplary embodiment of a semiconductor device according to the invention; and

FIG. 2B shows a cross section along line 2B-2B′ of FIG. 2A.

### DETAILED DESCRIPTION OF INVENTION

The following description encompasses the fabrication process and the purpose of the invention. It can be understood that this description is provided for the purpose of illustrating the fabrication process and the use of the invention and should not be taken in a limited sense. In the drawings or disclosure, the same or similar elements are represented or labeled by the same or similar symbols. Moreover, the shapes or thicknesses of the elements shown in the drawings may be magnified for simplicity and convenience. Additionally, the elements not shown or described in the drawings or disclosure are common elements which are well known in the art.

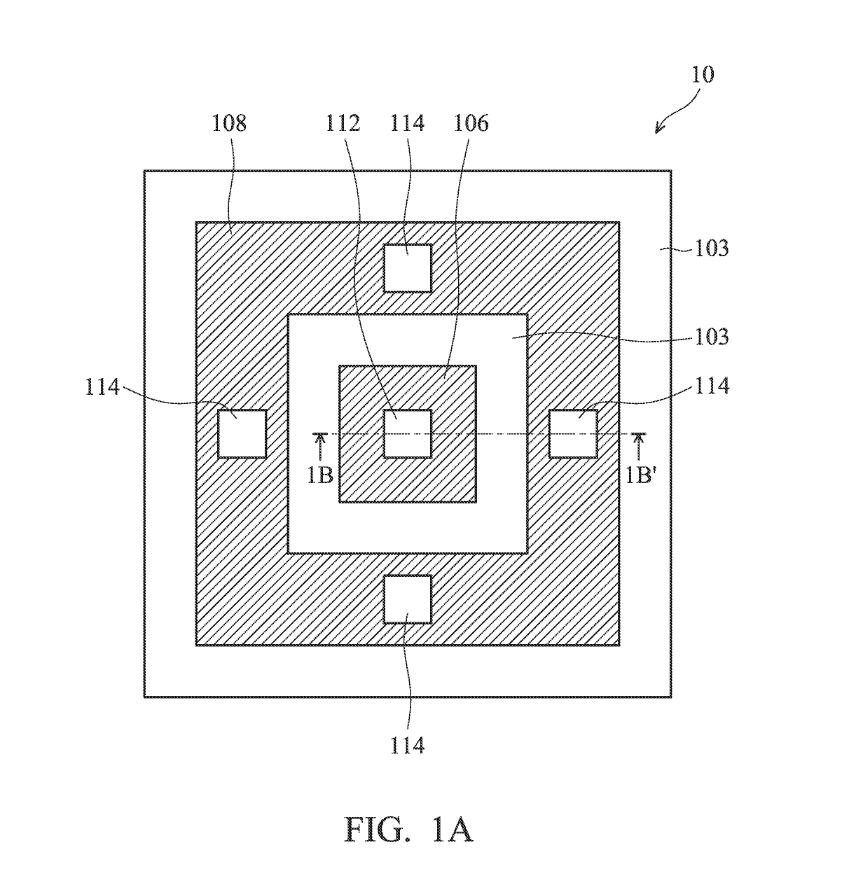

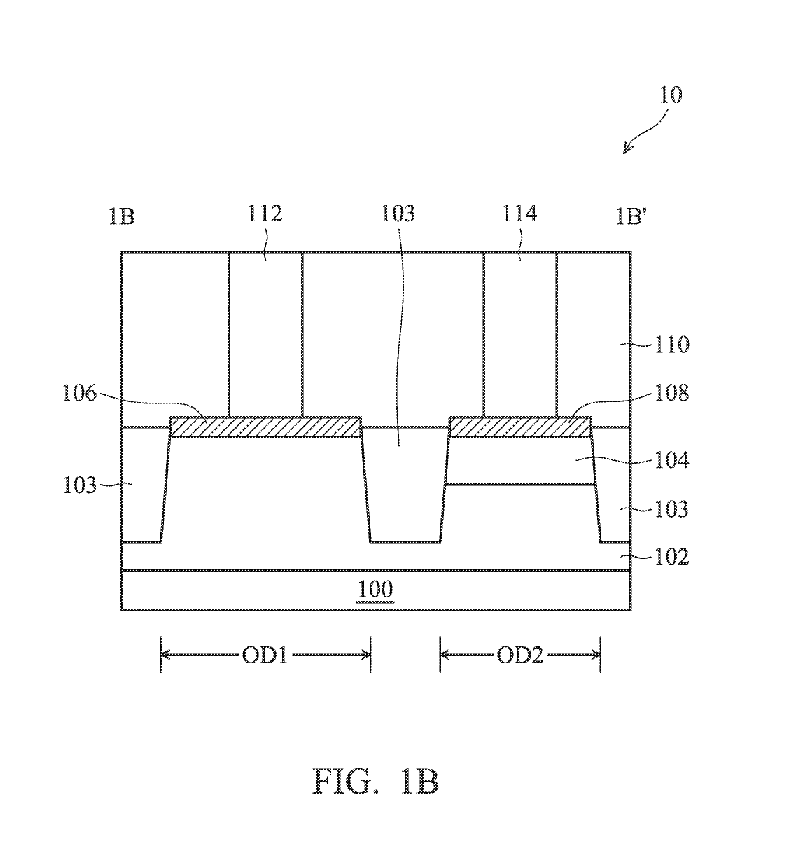

Referring to FIGS. 1A and 1B, which respectively illustrate a plan view of an exemplary embodiment of a semiconductor device 10 according to the invention and a cross section along line 1B-1B′ of FIG. 1A. The semiconductor device 10 may be implemented as a Schottky diode. The semiconductor device 10 comprises a semiconductor substrate 100. The semiconductor substrate 100 may have a conductivity type, such as n-type or p-type, and may comprise silicon or other group III, group IV, and/or or group V elements. A lightly doped region (which is also referred as to lightly doped well region or well region) 102 with an opposing conductive type with respect to the semiconductor substrate 100 is formed in the semiconductor substrate 100 by, for example, an implanting process or other well known doping processes. In the embodiment, the conductivity type of the semiconductor substrate 100 is p-type and that of the lightly doped well region 102 is n-type. The lightly doped well region 102 may be formed by implanting phosphorous or arsenic therein. In another embodiment, the lightly doped well region 102 may be formed by growing an epitaxial semiconductor layer on the semiconductor substrate 100, followed by performing an n-type impurity implantation process. An isolation structure 103 is formed in the lightly doped well region 102 to define a first active area OD1 and a second active area OD2 therein, wherein the first active area OD1 is separated from the second active area OD2 by the isolation structure 103. In the embodiment, a shallow trench isolation (STI) may be used as the isolation structure 103, although a well known local oxidation of silicon (LOCOS) is also applicable. The isolation structure 103 forms rings surrounding the first active area OD1 and the second active area OD2 (as indicated in FIG. 1B) in a top view, as shown in FIG. 1A. In one embodiment, the first active area OD1 and the second active area OD2 in the lightly doped well region 102 of the semiconductor substrate 100 may serve as cathode and anode regions of the Schottky diode, respectively.

A first metal silicide layer 106 and an optional second metal silicide layer 108 are disposed on the lightly doped well region 102 of the semiconductor substrate 100 corresponding to the cathode and anode regions of a Schottky diode, respectively. In one embodiment, the first metal silicide layer 106 and the second metal silicide layer 108 may comprise nickel silicide. Alternatively, the first metal silicide layer 106 and a second metal silicide layer 108 may comprise other suitable metal silicides, such as titanium silicide, cobalt silicide, tantalum silicide, platinum silicide or combinations thereof. The first metal silicide layer 106 and the second metal silicide layer 108 may be formed by a conventional self-aligned silicidation process. For example a metal layer (not shown) is selectivity formed on the lightly doped well region 102 corresponding to the first active area OD1 (i.e., cathode region) and the second active area OD2 (i.e., anode region). A high temperature annealing process is performed on the metal layer, such that the metal layer reacts with the underlying semiconductor substrate 100 to form the first metal silicide layer 106 and the second metal silicide layer 108 in direct contact with the lightly doped well region 102.

A heavily doped region 104 with the same conductivity type as that of the lightly doped well region 102 is formed in the lightly doped well region 102 and corresponds to the second active area OD2 (i.e., anode region), such that the second metal silicide layer 108 is beneath and in direct contact with the second metal silicide layer 108 to serve as the anode of the Schottky diode. In the embodiment, the conductivity type of the heavily doped region 104 is n-type. The heavily doped region 104 may be formed by implanting phosphorous or arsenic therein.

An interlayer dielectric (ILD) layer 110 is disposed on the semiconductor substrate 100 and may be composed of oxide, nitride, oxynitride, or combinations thereof, or low k material, such as fluorinated silicate glass (FSG), carbon doped oxide, methyl silsesquioxane (MSQ), hydrogen silsesquioxane (HSQ), or fluorine tetra-ethyl-orthosilicate (FTEOS), which serves as an interlayer dielectric (ILD) layer. The ILD layer 110 may be formed by, for example, chemical vapor deposition (CVD), low pressure chemical vapor deposition (LPCVD), plasma enhanced chemical vapor deposition (PECVD), high density plasma chemical vapor deposition (HDPCVD) or other deposition processes well known in the art.

Metal contacts 112 and 114 are disposed in the ILD layer 110 and in direct contact with the first metal silicide layer 106 and the second metal silicide layer 108, respectively, for electrical connection, wherein the metal contact 112 serves as the cathode of the Schottky diode. In one embodiment, the metal contacts 112 and 114 may comprise tungsten, although other suitable metals, such as aluminum, copper or combinations thereof are also applicable. The metal contacts 112 and 114 may be formed by performing a via hole etching process in the ILD layer 110 and then filling metal into the via holes. Metal layers (not shown) are disposed on the ILD layer 110 and are electrically connected to the respective metal contacts 112 and 114, thereby electrically connecting the Schottky diode comprising the cathode (i.e., metal contact 112), first and second metal silicide layers 106 and 108, the lightly doped well region 102, and the anode (i.e., heavily doped region 104 and metal contact 114) to other semiconductor devices or circuits (not shown).

According to the embodiment, note that the metal silicide layer 106 directly under the metal contact 112 is in direct contact with the lightly doped region 102 without any guard ring formed between the metal contact 112 and the lightly doped well region 102. Accordingly, the size of the semiconductor device (e.g., Schottky diode) 10 and the manufacturing costs are reduced as compared to the conventional Schottky diode with a guard ring. Moreover, since the silicide layer 106 between the metal contact 112 and the lightly doped well region 102 can mitigate damage at the metal/semiconductor interface caused by overetching during contact formation, the reliability and stability of the semiconductor device 10 can be enhanced.

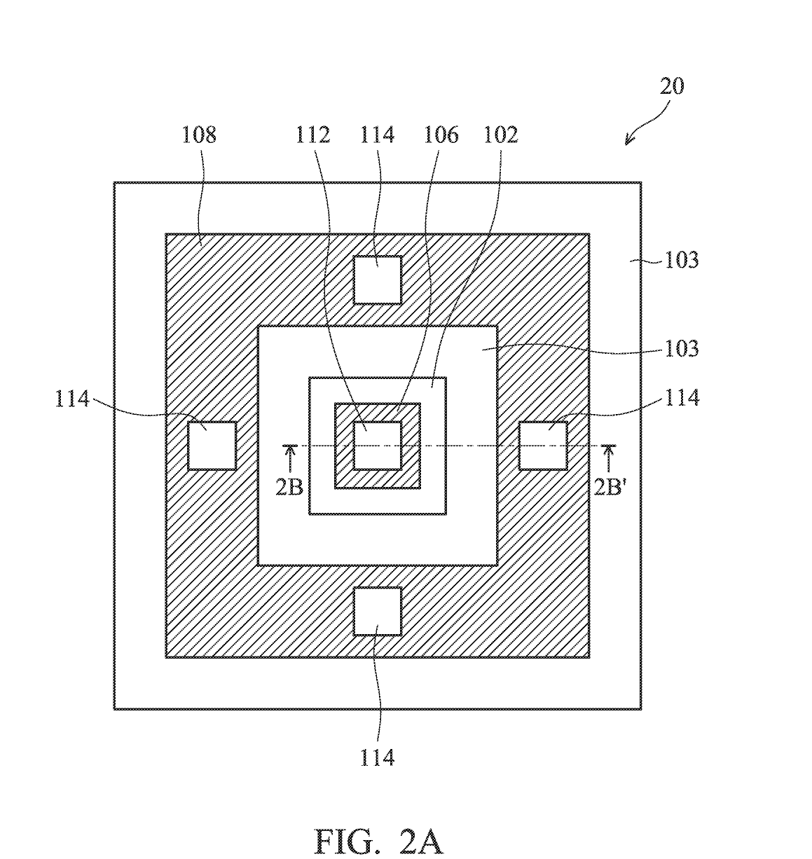

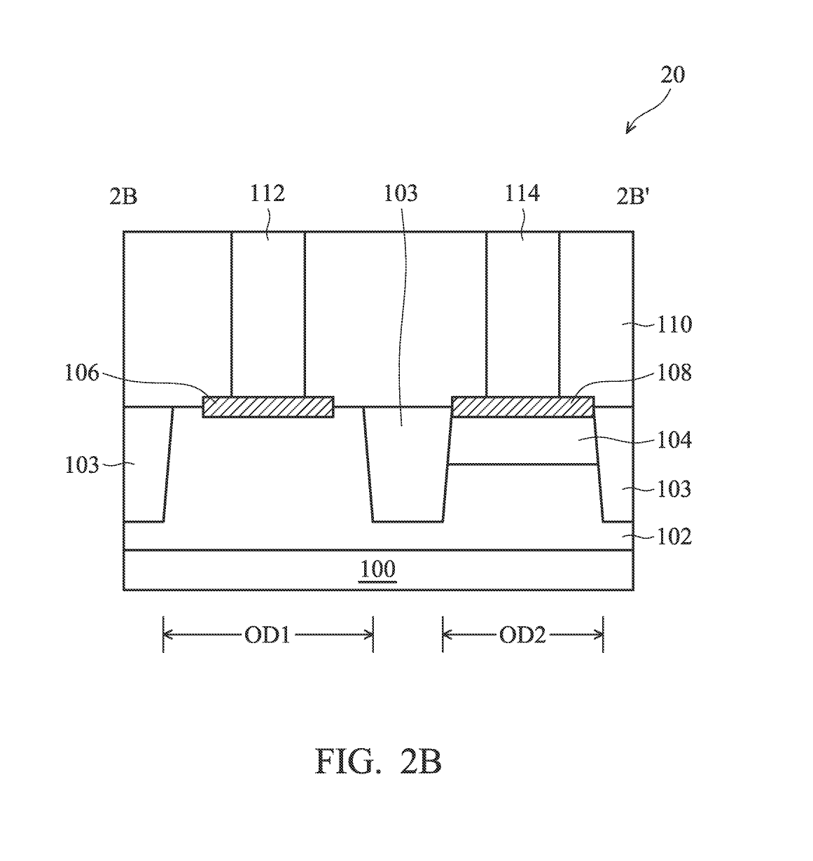

Referring to FIGS. 2A and 2B, which respectively illustrate a plan view of another exemplary embodiment of a semiconductor device 20 according to the invention and a cross section along line 2B-2B′ of FIG. 2A. Elements in FIGS. 2A and 2B that are the same as those in FIGS. 1A and 1B are labeled with the same reference numbers as in FIGS. 1A and 1B and are not described again for brevity. In the embodiment, the semiconductor device 20 has a similar structure as that of the semiconductor device 10 shown in FIGS. 1A and 1B except that the first metal silicide layer 106 is spaced apart from the adjacent isolation structure 103 to expose a portion of the lightly doped well region. In one embodiment, an additional resist protective oxide (RPO) layer (not shown) may be deposited on the semiconductor substrate 100 prior to formation of the metal silicide layer, and then the RPO layer may be selectively removed where silicidation is desired, such that the formation of the subsequent first metal silicide layer 106 is spaced apart from the adjacent isolation structure 103. In another embodiment, the first metal silicide layer 106 may be formed by the conventional silicidation process followed by lithography and etching processes, such that the first metal silicide layer 106 is spaced apart from the adjacent isolation structure 103. Trench etching, during STI structure (i.e., isolation structure 103) formation, may damage the semiconductor substrate 100 adjacent to the edge of the STI structure and the top surface of the STI structure 103 is typically not level with that of the semiconductor substrate 100, thereby detrimentally affecting the stability of the metal silicide adjacent to the top corners of the isolation structure 103. Accordingly, the first metal silicide layer 106 is spaced apart from the adjacent isolation structure 103, thus eliminating such problems as mentioned, so that the stability of the metal silicide can be enhanced. Also, the semiconductor device 10 can obtain the same benefits as the semiconductor device 10 as shown in FIGS. 1A and 1B.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A Schottky diode structure, comprising:
a semiconductor substrate having an anode region and a cathode region;
a lightly doped region with a predetermined conductivity type in the semiconductor substrate;
a metal contact overlying the lightly doped region and corresponds to the cathode region to serve as a cathode;
a first metal silicide layer beneath and electrically connected to the metal contact, wherein the first metal silicide layer, directly under the metal contact, is in direct contact with the lightly doped region; and
a heavily doped region with the predetermined conductivity type in the lightly doped region and corresponds to the anode region to serve as an anode.

2. The Schottky diode structure of claim 1, further comprising an isolation structure in the semiconductor substrate and between the anode and cathode regions.

3. The Schottky diode structure of claim 2, wherein the isolation structure is a shallow trench isolation structure.

4. The Schottky diode structure of claim 2, wherein the first metal silicide layer is spaced apart from the isolation structure to expose a portion of the lightly doped region.

5. The Schottky diode structure of claim 1, further comprising a second metal silicide layer in direct contact with the heavily doped region.

6. The Schottky diode structure of claim 5, wherein the first and second metal silicide layers comprise nickel silicide.

7. The Schottky diode structure of claim 1, wherein the predetermined

8. The Schottky diode structure of claim 1, wherein the predetermined conductive type is p-type.

9. The Schottky diode structure of claim 1, wherein the metal contact comprises tungsten.

10. A semiconductor device structure, comprising:
a semiconductor substrate having a well region with a predetermined conductivity type therein;
an isolation structure disposed in the well region to define a first active area and a second active area therein and separated from each other by the isolation structure;
a metal contact overlying the lightly doped well region of the first active area;
a first metal silicide layer beneath and electrically connected to the metal contact, wherein the first metal silicide layer, directly under the metal contact, is in direct contact with the well region; and
a heavily doped region with the predetermined conductivity type in the well region of the second active area.

11. The semiconductor device structure of claim 10, wherein the first metal silicide layer is spaced apart from the isolation structure to expose a portion of the well region.

12. The semiconductor device structure of claim 10, further comprising a second metal silicide layer in direct contact with the heavily doped region.

13. The semiconductor device structure of claim 12, wherein the first and second metal silicide layers comprise nickel silicide.

14. The semiconductor device structure of claim 10, wherein the predetermined conductive type is n-type.

15. The semiconductor device structure of claim 10, wherein the predetermined conductive type is p-type.

16. The semiconductor device structure of claim 10, wherein the metal contact comprises tungsten.
